(19) United States
(12) Patent Application Publication
(10) Pub. No.: US 2009/0267167 A1
(43) Pub. Date: Oct. 29, 2009

(54) DUAL-FACE FLUID COMPONENTS

(75) Inventors: Patrick Pouteau, Meylan (FR); Raymond Campagnolo, Grenoble (FR); Martine Cochet, Moirans (FR)

Correspondence Address: Nixon Peabody LLP, 200 Page Mill Road, Palo Alto, CA, 94306, US

(73) Assignee: COMMISSARIAT A L'ENERGIE ATOMIQUE, Paris (FR)

(21) Appl. No.: 12/441,371

(22) PCT Filed: Sep. 20, 2007
(86) PCT No.: PCT/EP2007/059954

§ 371 Date: Mar. 13, 2009

(30) Foreign Application Priority Data
Sep. 22, 2006 (FR) 0653907

(51) Int. Cl. H01L 29/66; H01L 21/465; H01L 31/00

(52) U.S. Cl. 257/431; 257/414; 438/48; 257/E21.485; 257/E29.166; 257/E31.001

(57) ABSTRACT

A fluid component includes at least one substrate of a material that can be etched and an etch stop layer for said material means for detecting the properties of a fluid and/or for activating said fluid and provided on a first side of said etch stop layer and means for receiving said fluid, formed in the substrate and provided on the second side of the etch stop layer.

### CROSS REFERENCE TO RELATED APPLICATIONS OR PRIORITY CLAIM

This application is a national phase of International Application No. PCT/EP2007/059954, entitled “DUAL-FACE FLUID COMPONENTS”, which was filed on Sep. 20, 2007, and which claims priority of French Patent Application No. 06 53907, filed Sep. 22, 2006.

### DESCRIPTION

### Technical Field and Prior Art

The invention relates to the field of fluid components, applied particularly to biological analysis devices.

The invention makes it possible to improve, firstly, the manufacture of fluid components, associated with MEMS functions and microelectronic functions, such as capillary components with integrated APS-CMOS technology (APS signifying Active Pixel Sensor) and, secondly, the integration and the packaging of such components; it facilitates the implementation, the system integration and the use.

The invention may in particular be applied to fluid components having, firstly, a deep structuring (reservoir and/or capillary and/or closing of the component) and, secondly, a structuring of electrodes.

APS components manufactured in CMOS technology are known for example from the document of F. Mallard et al., published in “Biosensors and Bioelectronics”, Vol. 20, 2005, p. 1813-1820.

An APS chip comprises an active zone, itself comprising a matrix of pixels, surrounded, completely or in part, by a zone of electronic processing microelectronic circuits. Said zone is surrounded by the zone of electrical contacts.

These contacts are thus localised on the edges of the component (on 1, or 2, or 3 or 4 sides). A pixel is constituted of an active zone (photodetector) and an electronic function zone for pre-processing the signal. The detection surface area (sum of all the surface areas of the photodetectors) of the detection matrix thus has a fill factor well below 100%.

To simplify, only the minimum representation of such a chip will be given hereafter, in other words the active zone of a pixel, a photodetector and the zone of electrical contact pick-ups with deposition of a passivation material (here silicon oxide).

FIG. 1 shows a sectional view of the technological stacking concerned. This figure represents the structure of a single detector, and not a matrix of detectors.

This figure shows the central zone 2, at the edge of which the contacts 4 are constituted of metal pads covered with a passivation (oxide) layer 5. Depassivated parts of these pads, not represented in the figure, enable the pick-up of the electrical contacts. The intermediate zone 6 is normally constituted of functions for electronically processing the signal from the central detection zone 2.

To integrate this technology in a fluid component, the principle as described in FIG. 2 may be adopted.

The chip is bonded to a memory film support 12, of PCB type, comprising two metal levels: one on each face and a via-hole level 14 enabling the two faces to be brought into contact.

A connection through contacts 16 with the memory film 12 is formed to pick-up the electrical contacts of the chip. A passivation resin 18 is deposited and cross-linked over all of this connection to protect all the electrical part of the component (contacts on the chip, connecting wires and electrical face of the memory film).

The memory film bearing the chip is assembled with a cap 20, comprising fluidic structurings to form a fluidic cavity, transferred onto the component.

Such an assembly has a certain number of problems.

From the point of view of the fluidic of the component, controlling the deposition zone of the protective resin 18 is a first problem.

The aim, in fact, is that the resin covers all of the metal surfaces, while at the same time having a minimum distribution on the surface of the chip, on penalty of encroaching upon the active zone.

In practice, a buffer zone of at least

500 μm needs to be provided between the contacts and the active zone of the chip. This represents a considerable loss of space on the chip.

In addition, the thickness of the resin 18 above the surface of the chip-memory film assembly 12 is a parameter that is not very reproducible. This brings a supplementary constraint to the depth of the fluidic of the component. This constraint considerably limits any work on the reduction of the volume of the fluidic cavity.

In the same way, the implementation of a transfer of the cap implies the existence of a transfer zone 13 between said cap and the support of the detection chip, a transfer zone that has to be sealed, leading to an additional widening of the chamber.

The not exactly reproducible character of the form of the passivation according to the creep of the resin 18 does not enable a good control of fluidic flows in the component and imposes for example dead zones in the corners of the components.

The volume of the fluidic part, defined in fact by the depth “p” structured in the cap 20, is difficult to reproduce. Furthermore, it is difficult to form depths “p” (see FIG. 2), in the cap, less than several hundreds of μm, for example 300 μm.

All this, namely the non reproducibility of the fluidic environment inducing a perturbation of the flow and the variation in the thickness of the liquid vein on the chip, is detrimental to the homogeneity of hybridisation on the bio-chips, particularly with multiple functionalised zones.

Finally, this assembly architecture imposes, in the biological reaction chamber, the presence of a resin or a polymer, the nature of which must be taken into account in the development of biological protocols.

The functionalisation (for example by biological probes) before assembly also poses a problem. The presence of metals (such as electrical contact pick-up pads), on the surface of the chip, renders unusable as such any biological functionalisation protocol that uses oxidation or reduction steps, with bases and acids.

The document of A.M. Jorgensen et al. (Sensors and actuators, B, 90, 2003, 15-21), describes the formation of one or several photodetectors on the rear face of a silicon substrate comprising a fluidic structuring on the front face of the substrate. In addition, as regards the fluidic connection of the component, a through etching is carried out on the side where the electrical contacts of the detectors are formed. This etching makes it possible to provide an access to the fluidic, in the front face of the substrate. Thus, on the rear face of the substrate, are found the contact pads of the detectors, as well as the fluidic holes or vias to form the inputs and outputs of the fluid component.

In this document, the fluidic part of the component is formed on a substrate of 350 μm thickness and over a depth of 72 μm±4 μm (for 60 min. of etching). There remains therefore a thickness of silicon, of around 278 μm, below the fluidic part.

The detector formed collects the electron-hole pairs created by the absorption of photons from the fluidic part of the component.

Given the absorption of silicon, these pairs are created in a layer of around 10 μm thickness, below the fluidic part. These pairs are collected by the junctions formed in the rear face of the component. Thus, they have to go through a high thickness of silicon (262 μm) before being collected by the junctions.

In order to avoid the recombination of electron-hole pairs, resort is made in this document to the use of a silicon substrate of high resistivity (>500Ω·cm). In addition, given the large distance to go through within the substrate, the photodetectors cannot be densified at will. For example, FIG. 4 of this document represents a chip of 1×2 cm², with 9 electrical contact pick-ups, which represents at best 4 detectors on the chip.

The photodetector technology used in this document is thus atypical and only enables a component to be formed that brings a certain number of constraints.

The problem of finding another device not having such drawbacks is thus posed.

Furthermore, the final step of forming an APS chip (and CMOS in general), before cutting of the chips, usually consists in carrying out a step of thinning substrates to facilitate the packaging steps. The substrates are thinned up to a thickness between, for example, 700 μm and 100 μm.

Also sought is a structure, and a method enabling it to be formed, in which the problems posed by the implementation of a transfer technique, in particular the alignment of the fluidic vis-à-vis the active surface, is not posed.

### DESCRIPTION OF THE INVENTION

The invention relates to a chip or a fluid component or an analysis device comprising:

at least one substrate of a material that can be etched, and an etch stop layer for said material, said layer having a first and a second side,

means for detecting at least one property of a fluid and/or for activating said fluid, formed on the first side of said etch stop layer,

a fluidic part to receive said fluid, formed in the substrate, on the second side of the etch stop layer.

The means for detecting at least one property of a fluid and/or for activating said fluid are formed on a first side of the etch stop layer: one and/or the other of said means may be formed in or on the etch stop layer, or in or on a layer situated on the stop layer.

Means for detecting the properties of a fluid signify means that make it possible to characterise one or several physical and/or chemical properties of said fluid, for example the temperature, and/or the photonic activity, and/or the pH, and/or the salinity, and/or the electrochemical potential, etc.

Means for activating a fluid signify means that make it possible to modify one or several physical and/or chemical properties of said fluid, for example means for heating, and/or agitating and/or lighting the fluid.

According to the invention, one face of a component comprising a stop layer, for example the rear face of an APS chip, is used to form the fluidic part of the device in at least a part of the substrate which would otherwise, according to known techniques, be eliminated. The fluidic part and the detection and/or activation part are separated by the stop layer. Said stop layer eliminates any fluidic circulation or communication between the fluidic part and the detection and/or activation part.

The component according to the invention further comprises a cap that closes the fluidic part. Said cap is placed preferentially in a sealed manner. The sealing may be obtained by deposition of an epoxy adhesive by screen printing, prior to the assembly of the fluid component and the cap. Such an assembly method is described in patent application WO-A-2004/112961, in the names of the applicants.

According to an alternative of the invention, the assembly of the cap and the fluid component, facing the fluidic part, is reversible.

According to another alternative of the invention, the cap comprises fluidic communication means enabling a fluid exchange between the fluidic part and any exterior fluid element. Such fluidic communication means may be, for example, through holes surmounted by a connector socket, enabling the fluid component to be connected to a pump or a pressurised reservoir.

Alternatively, the cap may be constituted by a more complex fluidic element, such as a fluidic card, for example of “Lab on a card” type, or a microfluid component. In particular, said microfluid component is a fluid component according to the invention.

A superficial layer may moreover be formed on the stop layer, on the side of the detecting and/or activating means.

According to a specific embodiment, the detecting and/or activating means are formed in a superficial layer on the stop layer of the fluid component. This layer is preferentially constituted of a semi-conductor material. The stop layer and the substrate may be the three layers of an SOI (silicon on insulator) substrate.

Means for detecting may be at least in part formed in or on this superficial layer.

An SOI substrate may thus be used to form the detector part, for example in a CMOS type technology, of the chip or the fluid component or the analysis device according to the invention.

The fluidic part is thus defined in, or below, the chip, said chip being for example formed in a CMOS type technology.

The stop layer, the buried oxide in the case of the SOI substrate, forms an etch stop layer on the rear face to define the depth of the fluidic part of the component in the support. The latter is for example formed of silicon or, more generally, of semi-conductor material.

The means for detecting may comprise at least one photodetector.

A device according to the invention may further comprise a passivation and/or stiffening layer. This layer is formed for example of silicon oxide directly on the means for detecting/activating or on the superficial layer.

Means for detecting the electrical properties of a fluid may be formed, for example at least in part in the etch stop layer.

A part of these means is in contact with the fluidic part.

Moreover, means for activating a fluid by electrowetting may also be formed, if necessary with electronic means for controlling the means for activating a fluid by electrowetting.

Reservoirs of fluid may also be formed in the substrate.

Preferably the stop layer, and if necessary the superficial layer formed on the stop layer, have a thickness less than 10 μm.

In a component according to the invention, the fluidic part, which makes it possible to receive a fluid, may have a well controlled depth, for example less than 300 μm or 100 μm.

The means for detecting and/or activating may be connected to depassivated electrodes situated on the first side of said etch stop layer.

The invention also makes it possible to form a high density matrix of detectors comprising a plurality of components as described above, separated from each other by a distance of less than 10 μm.

According to the invention, the technology of forming the fluidic part is thus adapted to a microelectronic technology, for example of CMOS type.

A deep etching of the semi-conductor material of the support is carried out, so that an emission of photons from the fluid can attain the means for detecting formed on the other face of the component.

A chip or a component according to the invention may comprise a stiffening substrate.

A functionalisation, for example with biological probes, such as nucleic probes, may moreover be carried out, in the fluidic part, intended to receive the fluid.

The invention benefits in particular from the possibility of using APS technology to form a high density matrix of detectors (at a spacing that may be less than 10 μm), which is impossible with the technology described in the prior art already cited.

In addition, the input via-holes in the fluidic part are not formed through the support of the substrate used. Useful surface area is therefore not lost on the detection part of the component. This also makes it possible to carry out aggressive chemical steps—in collective manufacture—on the fluidic part, without giving access to the other face of the substrate (in order to avoid deterioration of the means for detecting situated on the other face).

The invention makes it possible to take advantage of the use of an SOI substrate and the associated CMOS technology. It moreover makes it possible to have an advantageous embodiment of the fluidic part.

The invention also relates to a method of forming at least one fluid component comprising:

a) the selection of a substrate of a material that can be etched, provided with an etch stop layer for said material,

b) the formation of means for detecting the properties of a fluid and/or for activating said fluid, on a first side of said etch stop layer,

c) the formation of a fluidic part, to receive said fluid, in the substrate, by etching of said substrate from the second side of the etch stop layer and stopping the etching on said stop layer.

According to an alternative of the method, said method makes it possible to carry out the collective manufacture of fluid components. A plurality of fluid components according to the invention may thus be formed. The method then comprises a final step of dissociating said fluid components, carried out collectively in order to make them independent of each other.

The invention also relates to the use of a component, or a matrix, as described above, for implementing a biological analysis.

### BRIEF DESCRIPTION OF DRAWINGS

FIGS. 1 and 2 represent a known device, of APS-CMOS type, without and with cap for protecting and defining the fluidic part,

FIGS. 3A and 3B represent components or substrates that may be used for forming a fluid component according to the invention,

FIG. 4A schematically represents the implantation of a CMOS component on a semi-conductor on insulator type substrate,

FIG. 4B represents a substrate treated according to the invention with a cap on the side of the fluidic part,

FIGS. 5A and 5B represent a device according to the invention with metal electrodes and contact pick-ups facing the fluidic part of the component,

FIG. 6 represents a device according to the invention with metal electrodes in the fluidic part of the component and a CMOS structure insulated from the fluidic part by an oxide layer of an SOI substrate,

FIGS. 7 and 8 represent devices according to the invention with means of displacement by electrowetting.

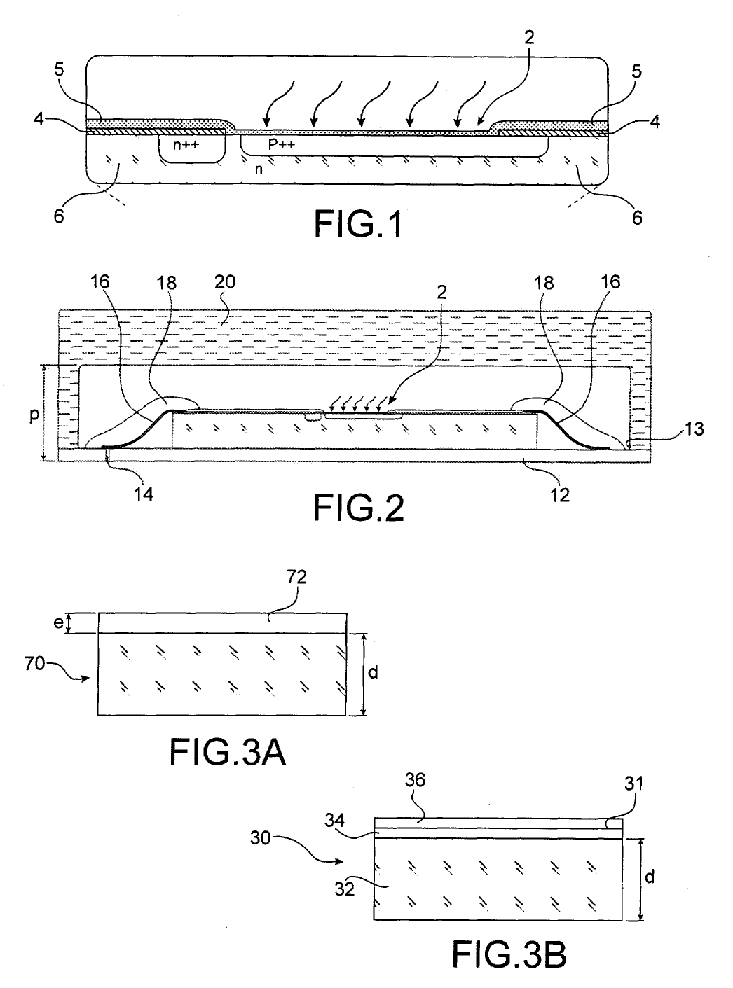

### DETAILED DESCRIPTION OF SPECIFIC EMBODIMENTS

To simplify the description of the invention, only a simplified version of a detection chip is shown hereafter, by the representation of a minimum version, for example a single photodetector with two implantation zones and two electrical contact pick-ups. The invention encompasses the formation with one or several more complex components.

In the different embodiments described below, a stop layer is used to etch the fluidic part (or means for receiving a fluid) of a fluid component, said stop layer may result for example from a superficial oxidation of a semi-conductor substrate or be the insulating layer of an SOI or semi-conductor on insulator type component.

Thus, in FIG. 3A is represented a substrate 70 made of silicon on which a superficial layer 72 is obtained by oxidation. Alternatively, the layer 72 could be a layer of silicon nitride Si₃N₄. The layer 72 and the substrate 70 form a single substrate.

In FIG. 3B is represented an SOI substrate 30, which typically comprises a support 32 made of semi-conductor material, a layer 34 of dielectric material, and a superficial layer 36 of semi-conductor material.

In both cases, it is possible to form electrical and/or magnetic and/or thermal and/or other detecting and/or activating means and/or MEMS type means, either in the layer 72 or in the superficial layer 36 of semi-conductor material and if necessary in the layer 34. The layer 72 or the layer 34 will serve as stop layer during a step of etching of the fluidic part in the substrate 70 or in the support 32. It ensues that the fluidic part may be formed easily, its depth “d” being uniquely determined by the thickness of the part of the substrate or the support situated below the stop layer less any partial thinning of the substrate.

For example the layer 72 (or the assembly of two layers 34 and 36) has a thickness “e” of several μm, for example between 1 μm and 10 μm, whereas the substrate 70 or the support 32 has a thickness less than several hundreds of μm, for example less than 500 μm or between 10 μm and 50 μm or 90 μm or instead between 10 μm and 300 μm.

The present invention makes it possible to avoid transfer techniques with alignment of the fluidic part on the detection or activation part, as explained below in the different examples.

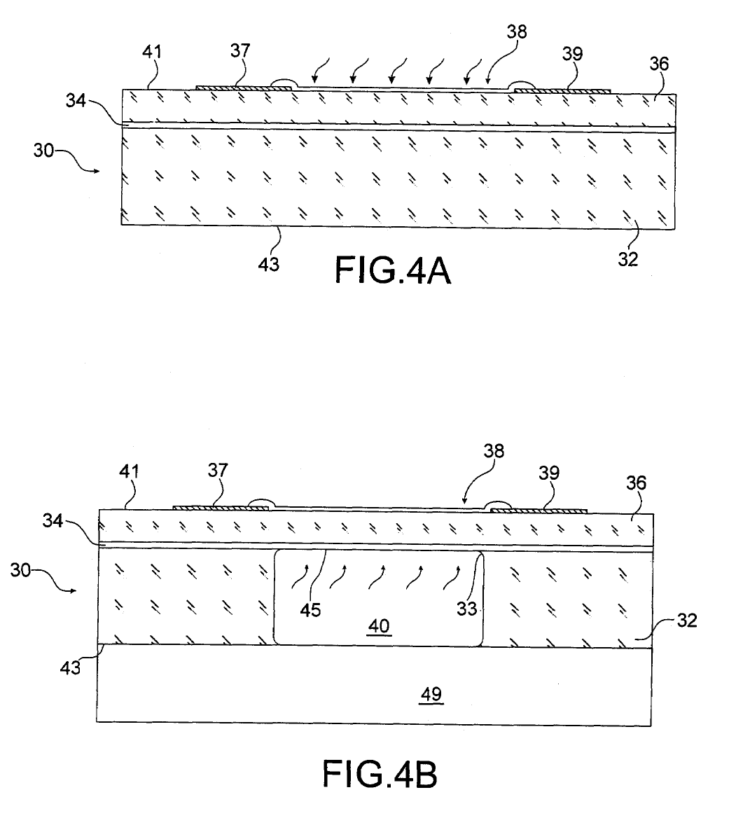

FIG. 4A shows, in the case of a CMOS chip, how this may be formed on an SOI substrate within the scope of a device according to the present invention.

A detector 38, here based on a component stemming from a CMOS technology, is formed in or on the superficial semi-conductor layer 36 of the SOI substrate, on a first side of the stop layer. Electrodes 37, 39 make it possible to assure the contacts with the detector. The assembly is arranged on the front face 41 of the SOI substrate.

A method of forming the chip or the detector 38 may be a known method, applied to an SOI substrate. Known CMOS techniques are thus used to form the chip or the detector.

FIG. 4B shows how may be arranged, directly below the chip, a second side of the stop layer, a fluidic part or chamber 40 of the component, by deep etching on the rear face of the SOI substrate. The support 32 is etched, the layer 34 forming an etch stop layer.

A passivation layer may be formed on the front face 41 of the detection part of the chip before carrying out the deep etching on the rear face 43. It is eliminated after this step of deep etching. A stiffening substrate may be assembled in a removable manner or not on the front face 41 to guard against any fragilisation of the substrate 32 during the step of deep etching.

The fluidic part of a device according to the invention is thus well controlled. Indeed, by a method according to the invention, the steps of forming the fluidic implement alignment methods, such as those used in micro technology, which guarantee the accuracy of positioning and collective manufacture.

Compared to a conventional solution of deep etching of the fluidic—for example in a cap which is then transferred onto the assembly as in the case of the device of FIG. 2—the invention makes it possible to avoid the phase of precise control of the etching depth. Indeed, in the invention, this stops on the stop layer, here the layer 34 of silicon oxide.

To achieve the closing of the fluidic part, a cap 49, preferably flat, is assembled with the fluid component. Said cap is for example made of glass, silicon, plastic or metal.

Such a component is compatible with methods of functionalising substrates.

Once the fluidic part or the chamber is formed on the face opposite to that bearing the electrical part 38 of the substrate, chemical functionalisation steps may be carried out on one face 45 of the substrate, on the fluidic side, without touching its other face.

These steps may thus be carried out on the side of the fluidic part 40 and then if necessary localise biological probes at the base of this fluidic part.

The component thereby formed is compatible with a functionalisation chemistry, such as described in FR 2 818 662, for placing biological probes inside the fluidic part.

The invention makes it possible to use advisedly the support part 32 made of semi-conductor material, here in silicon, which is considered as unnecessary within the context of known techniques and often removed by thinning of the substrate after manufacture of the chip.

The invention does not necessitate passivation of the contact pick-up electrodes 37, 39, since these are situated on the face 41 of the substrate (on the side of the stop layer dedicated to the detection), opposite to the face 43 from which the fluidic part or the chamber 40 (on the other side of the stop layer) is formed. Furthermore, by construction, no fluidic communication is established between these two faces 41, 43 or between the chamber 40 and the detection part.

The study of the interface zone 33 between the fluidic part and the stop layer can easily show that there has been no transfer, but that a single and same substrate has been used for the two parts, firstly the detecting and/or activating part and secondly the fluidic part.

The invention moreover avoids the loss of space which would have been necessary on the component to allow a passivation resin (such as the resin 18 of FIG. 2) to creep or to achieve the sealing of the fluidic part of the component (on account of, in particular, a transfer step, such as that making it possible to transfer the cap 20 in the case of FIG. 2).

It is compatible with a collective manufacture of the fluidic part of the component, facing each chip, that said component is of CMOS type or other. Any other technology based on a semi-conductor may be envisaged, for example NMOS, or BiCMOS.

A fluid component according to the invention is directly compatible with circuit transfer techniques (contacts through microbeads, etc.) of “pick and place” type, techniques that are already developed for silicon chips. This involves the transfer of the finished component onto an exterior circuit.

The invention provides a real simplification as regards the packaging and the implementation of the component.

Preferably, and in so far as a “fluidic below IC” (where IC designates integrated circuit) technology is carried out, the dimensions for the implementation of two functions, detection and fluidic, are nearly identical.

The invention may have other applications than that explained above, with the same advantages as those previously cited. An electrical detection, for example by CMOS chip, may also be formed within the scope of the invention.

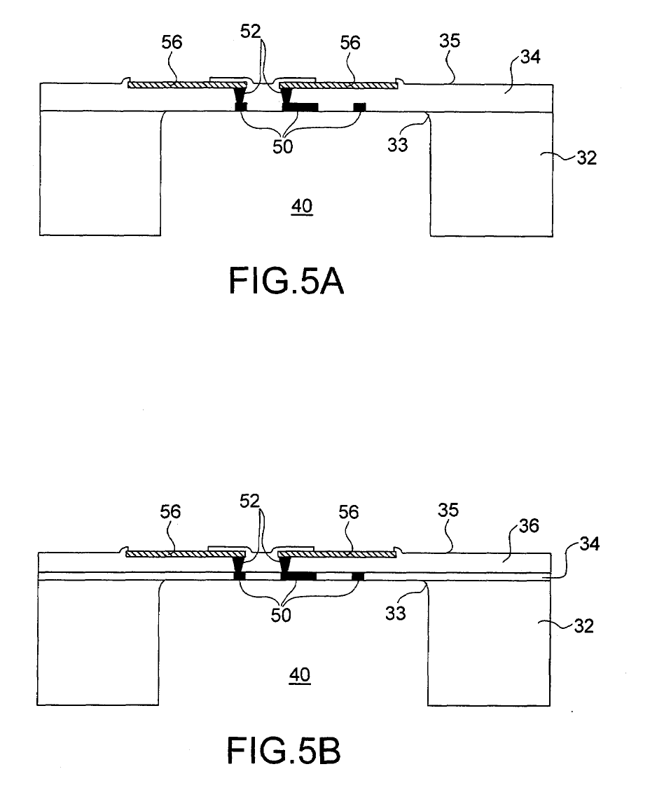

As illustrated in FIG. 5A, during the formation of the CMOS chip, one of the metal levels may be formed by etching all the superficial semi-conductor layer of the front face of an SOI substrate 30 (see structure of FIG. 3B) up to the layer 34 of silicon oxide, which forms a stop layer on the support 32. Metal electrodes 50, which will be facing the fluidic part or chamber 40 in the final component, are then formed.

The etching of the fluidic part 40 of the component is then possible, as in the previous embodiment, from the rear face of the SOI, stopping on the oxide 34 and on the metal layer of the chip. Electric via-holes 52 are formed through the layer 34 to connect the electrodes 50 to passivated contact pick-ups 56, localised on the other face 35, not exposed to the fluid, of the layer 34. The electrodes 50, exposed to a fluid situated in the fluidic part 40, will make it possible to have access to electrical properties of said fluidic part.

In this embodiment with electrical detection, the superficial semi-conductor layer 36 of the front face may not be eliminated: thus, in FIG. 5B, is represented an embodiment in which a part of this superficial semi-conductor layer 36 remains. In this case, the contact pick-ups 56 may be formed on the front face of this same layer 36.

The component of FIG. 5A may also be obtained from a starting substrate such as that of FIG. 3A, comprising a substrate 70 with stop layer on the surface.

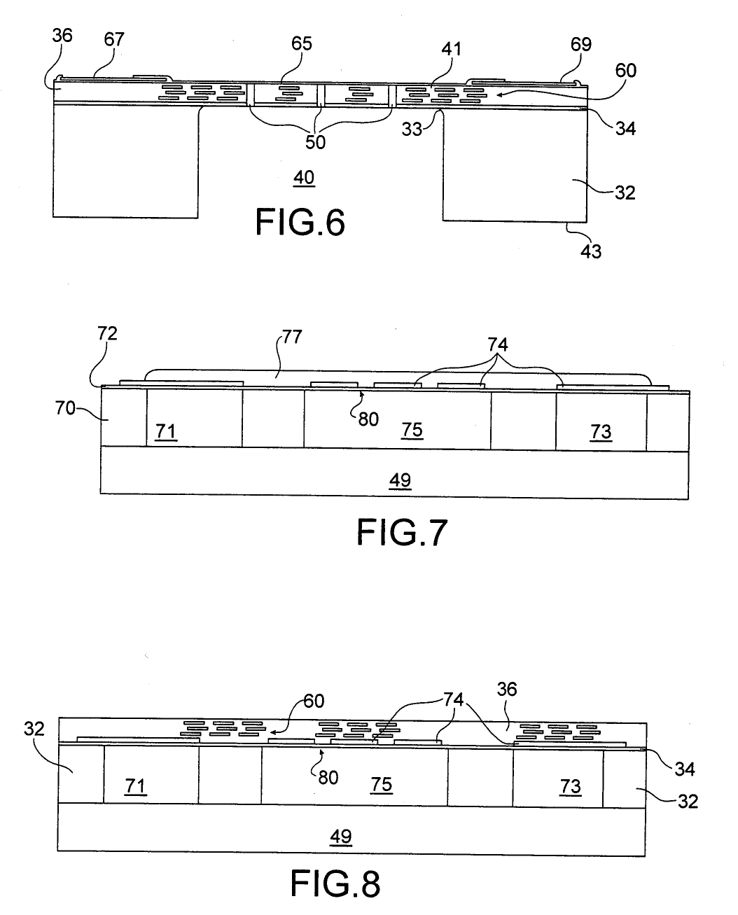

According to yet another embodiment, illustrated in FIG. 6, metal electrodes 50 may be formed, passing through the layer 34 and thus in contact with the fluidic part 40 in the final component. A CMOS structure 60 is formed in the layer 36 and is insulated from the fluidic part of the component by the oxide layer 34 of the SOI substrate. The reference 65 designates a passivation layer on the front face 41 of the substrate. Contact pick-ups 67, 69 are also formed on the front face and partially depassivated.

In the case of FIGS. 5A-6, here again, an examination of the interface zone 33 is sufficient to reveal that there is no trace of transfer of the fluidic part on the detection part.

The technology of displacement and manipulation of drops or fluids by electrowetting, known for example from the document FR 2 841 063 or the article of M.G. Polack et al. “Electrowetting based actuation of droplets for integrated microfluidics”, Lab Chip, 2002, 2, 96-101, may also be used in the formation of a device according to the invention.

It implements a fluidic structuring around zones of metal electrowetting electrodes. In combination with such a component for displacing fluid by electrowetting, it is also possible to form reservoirs for distributing reagents or even define a closed volume of the active part of the component, or delimit a volume of oil.

The invention may, here again, be used to bring a simplification of the packaging and the use of such components.

To do this, if only a matrix of electrodes without an integrated control electronic such as a multiplexer is simply required, a semi-conductor substrate 70 may be used as starting wafer, such as that illustrated in FIG. 3A, instead of an SOI substrate (FIG. 7).

This may be a silicon substrate 70, oxidised to obtain a desired thickness of dielectric layer 72 in order to fulfil the function of insulating the electrowetting device. The metal electrodes 74 are then formed on the surface of this oxide 72 without it being necessary to passivate the front face 79. The fluidic part or the fluidic structuring may then be formed, as in the other embodiments, by the rear face of the substrate, by using the silicon oxide 72 as stop layer. A deposition of hydrophobic material 80 may be carried out on the rear face, in order to favour the effect of electrowetting.

The diagram of FIG. 7 shows in section a simplified technology of a chip with displacement of fluid by electrowetting, with fluidic structuring on the rear face. The method of etching the fluidic part of the component may be simplified since it does not participate in the definition of the rectional volume: said volume is defined by the number of activated electrowetting electrodes.

The fluidic part may comprise several reservoirs: there are three of them, referenced 71, 73, 75 in FIG. 7. Specific functions may be assigned to certain reservoirs: for example, the reservoir 75 may be a reaction and drop displacement zone, said drops may be brought from neighbouring reservoirs 71, 73.

A passivation and stiffening oxide layer 77 may be formed on the front face of the substrate.

If it is wished to form electronic means for managing matrices of electrodes, it is possible to use a CMOS technology on the front face of a semi-conductor on insulator substrate, as in FIGS. 4A to 6. Thus, FIG. 8 again represents a semi-conductor on insulator structure with its three levels 32, 34, 36, as in FIGS. 4A and 4B, and electrowetting electrodes 74 formed on the front face of an insulating layer 34 covering a hydrophobic layer 80 on the rear face.

Electronic components 60, for example of CMOS type, are formed in the semi-conductor layer 36. The other references designate identical or similar elements to those of FIG. 7.

In the case where a semi-conductor on insulator (SOI) substrate is used to form the electrodes, these may be not only metal, but alternatively made of doped semi-conductor, for example made of doped silicon.

Whatever the embodiment of the invention, embodiments may be combined with electrical and optical detection. For instance, one and/or the other of these detection techniques may be combined with displacement electrodes by electrowetting. Alternatively, or in combination with optical and/or electrical and/or displacement by electrowetting functions, any type of detector and/or actuator may be incorporated, for example in MEMS technology derived from CMOS technology.

Generally speaking, the fluidic part is formed after the detection part, because it is preferable to form the part with highest topology at the end. But it is also possible to proceed in the reverse order.

To etch the fluidic part, an etching method faster than that described in the prior art, in particular in the document of A.M. Jorgensen et al. already cited above, may be used (4 μm/min instead of 1 μm/min for this known technique).

Thus, no particular criterion (in particular as regards its resistivity) is imposed on the support, for example made of silicon, and no modification to it is made (standard CMOS resistivity). Yet, in the known technique, such an adaptation is necessary to form a suitable electronic function.

The invention makes it possible, in particular, to form a fluid component comprising means for detecting and/or activating and means—known as fluidic means—forming a fluidic part to receive a fluid, characterised in that:

the means for detecting and/or activating are formed in or on a superficial layer of semi-conductor material or in or on the insulating layer of a substrate of semi-conductor on insulator type,

the fluidic part is arranged in the support part of said semi-conductor on insulator type substrate.

1. Fluid component comprising:
at least one substrate of a material that can be etched, and a stop layer for etching of said material,
means for detecting properties of a fluid and/or for activating said fluid, formed on a first side of said etch stop layer,
a fluidic part to receive said fluid, formed in the substrate, on a second side of the etch stop layer.

2. Component according to claim 1, further comprising a cap that closes the fluidic part.

3. Component according to claim 2, in which the cap comprises fluidic communication means enabling a fluidic exchange between the fluidic part and any exterior fluidic element.

4. Component according to claim 1, in which the means for detecting the properties and/or activating said fluid are formed in a superficial layer on the stop layer.

5. Component according to claim 4, in which the superficial layer, the stop layer and the substrate constitute an SOI substrate.

6. Component according to claim 4, comprising means for detecting, at least a part of which is formed in the superficial layer.

7. Component according to claim 1, wherein the means for detecting comprise at least one photodetector.

8. Component according to claim 6, wherein the means for detecting are of CMOS type.

9. Component according to claim 1, wherein the stop layer is made of silicon nitride or silicon oxide.

10. Component according to claim 1, further comprising a passivation and/or stiffening layer.

11. Component according to claim 1, comprising means for detecting at least one electrical property of a fluid.

12. Component according to claim 11, wherein the means for detecting at least one electrical property are in contact with the fluidic part.

13. Component according to claim 12, wherein the electrical means for detecting are formed at least in part in the etch stop layer.

14. Component according to claim 1, comprising means for activating a fluid by electrowetting.

15. Component according to claim 14, further comprising electronic means for controlling the means for activating a fluid by electrowetting.

16. Component according to claim 15, further comprising reservoirs of fluid formed in the substrate.

17. Component according to claim 1, wherein the stop layer, and if necessary the superficial layer formed on the stop layer, have a thickness less than
10 μm.

18. Component according to claim 1, wherein the fluidic part has a depth less than 300 μm.

19. Component according to claim 1, wherein the means for detecting and/or activating are connected to depassivated electrodes situated on the first side of said etch stop layer.

20. Component according to claim 1, further comprising a supplementary stiffening substrate.

21. Component according to claim 1, further comprising a functionalisation with biological probes, such as nucleic probes.

22. High density matrix of detectors comprising a plurality of components according to claim 1, separated from each other by a distance less than
10 μm.

23. Use of a component according to claim 1, for implementing a biological analysis.

24. Method of forming at least one fluid component comprising:
a) the selection of a substrate of a material that can be etched, provided with an etch stop layer for said material, formed integrally with said substrate,
b) the formation of means for detecting properties of a fluid and/or for activating said fluid, on a first side of said etch stop layer,
c) the formation of a fluidic part to receive said fluid, in the substrate, by etching of said substrate from the second side of the etch stop layer and stopping the etching on this stop layer,
d) the transfer and the sealing of a cap to close the fluidic part.

25. Method according to claim 26, wherein step a) is following by a step of forming a passivation layer before carrying out step b).

26. Method according to claim 24, further comprising a step of functionalisation of the fluidic part.

27. Method of forming, according to claim 24, a plurality of fluid components, comprising a final step of dissociating said fluid components.
